(19) United States
(12) Patent Application Publication
(10) Pub. No.: US 2026/0282979 A1
(43) Pub. Date: Sep. 17, 2026

(54) INTEGRATED SUBSTRATE, MANUFACTURING METHOD THEREOF AND ELECTRONIC DEVICE

(71) Applicants: Beijing BOE Sensor Technology Co., Ltd., Beijing (CN); BOE Technology Group Co., Ltd., Beijing (CN); Beijing BOE Technology Development Co., Ltd., Beijing (CN)

(72) Inventors: Can ZHANG, Beijing (CN); Yue LI, Beijing (CN); Yuelei XIAO, Beijing (CN); Qichang AN, Beijing (CN); Huiying LI, Beijing (CN); Yifan WU, Beijing (CN); Biqi LI, Beijing (CN); Yingying ZHAO, Beijing (CN); Shuang XU, Beijing (CN); Kuili REN, Beijing (CN)

(21) Appl. No.: 19/470,469

(22) PCT Filed: Nov. 16, 2023
(86) PCT No.: PCT/CN2023/131951

§ 371 Date: Sep. 29, 2025

(51) Int. Cl. H10W 70/65; H01F 27/28; H10W 70/05; H10W 70/63

(52) U.S. Cl. CPC H10W 70/6565; H01F 27/2804; H10W 70/095; H10W 70/635

(57) ABSTRACT

An integrated substrate includes: a dielectric substrate having a first surface and a second surface opposite to each other in a thickness direction of the dielectric substrate, where the dielectric substrate includes a first connection via running through the dielectric substrate in the thickness direction of the dielectric substrate; a first buffer layer on the first surface side and provided with a first hollowed-out pattern; a second buffer layer on the second surface side and provided with a second hollowed-out pattern; a first conductive structure in the first hollowed-out pattern; a second conductive structure in the second hollowed-out pattern; and a first connection electrode in the first connection via, where the first conductive structure and the second conductive structure are connected through, and form an integral structure with, the first connection electrode.

### TECHNICAL FIELD

The present disclosure belongs to the technical field of passive devices, and specifically relates to an integrated substrate, a manufacturing method thereof and electronic device.

### BACKGROUND

Along with the constant development of the current consumer electronics industry, mobile communication terminals, represented by mobile phones, particularly 5G mobile phones, have also experienced rapid development. More and more frequency bands of signals are needed to be processed by mobile phones, and the number of required radio frequency chips is also increased, while the mobile phone forms popular with consumers are continuously developed toward miniaturization, lightweight and long endurance. In a conventional mobile phone, a large number of discrete devices, such as resistors, capacitors, inductors, filters and the like, are present on a radio frequency PCB, which have the defects of large volume, high power consumption, multiple welding spots, and large parasitic parameter changes, making it difficult to meet future requirements. The interconnection, matching and the like of the radio frequency chips require integrated passive devices of small area, high performance and good consistency. Current commercially available integrated passive devices are mainly based on a silicon (Si) substrates or a gallium arsenide (GaAs) substrate. The Si-based integrated passive device has the advantage of low price, but the microwave loss of the device is relatively high due to trace impurities in Si itself (poor insulation), resulting in unsatisfactory performance; while the GaAs-based integrated passive device has the advantage of excellent performance, but is expensive.

### SUMMARY

To solve at least one of the technical problems in the existing art, the present disclosure provides an integrated substrate, a manufacturing method thereof and electronic device.

An embodiment of the present disclosure provides an integrated substrate, including:
a dielectric substrate having a first surface and a second surface opposite to each other in a thickness direction of the dielectric substrate, wherein the dielectric substrate includes a first connection via running through the dielectric substrate in the thickness direction of the dielectric substrate;
a first buffer layer on the first surface side and provided with a first hollowed-out pattern;
a second buffer layer on the second surface side and provided with a second hollowed-out pattern;
a first conductive structure in the first hollowed-out pattern;
a second conductive structure in the second hollowed-out pattern; and
a first connection electrode in the first connection via, wherein the first conductive structure and the second conductive structure are connected through, and form an integral structure with, the first connection electrode.

The integrated substrate further includes a first protective layer on a side of the first conductive structure facing away from the dielectric substrate.

The first connection electrode is filled into the first connection via.

The first conductive structure and the second conductive structure are electrically connected through the first connection electrode to form a coil structure of an inductor.

An embodiment of the present disclosure provides a method for manufacturing an integrated substrate, including:
providing a dielectric substrate having a first surface and a second surface opposite to each other in a thickness direction of the dielectric substrate, wherein the dielectric substrate includes a first connection via running through the dielectric substrate in the thickness direction of the dielectric substrate;
forming a pattern including a first buffer layer on the first surface through a patterning process, wherein a first hollowed-out pattern of the first buffer layer is the same as a pattern of a first conductive structure to be formed;
forming a pattern including a second buffer layer on the second surface through a patterning process, wherein a second hollowed-out pattern of the second buffer layer is the same as a pattern of a second conductive structures to be formed;
forming seed layers on a side of the first buffer layer facing away from the first surface, and on a side of the second buffer layer facing away from the second surface, and electroplating the seed layers to form a first conductive layer on the first surface side, a second conductive layer on the second surface side, and a first connection electrode in the first connection via;
patterning the first conductive layer to form a pattern including the first conductive structure; and
patterning the second conductive layer to form a pattern including the second conductive structures, wherein the second conductive structure is connected to the first conductive structure through the first connection electrode to form an integral structure.

The step of patterning the first conductive layer to form the pattern including the first conductive structure includes:
removing, through chemical mechanical polishing, a part of the first conductive layer on a surface of the first buffer layer facing away from the dielectric substrate, and planarizing a surface facing away from the dielectric substrate of a part of the first conductive layer in the first hollowed-out pattern, to form the first conductive structure.

The step of patterning the second conductive layer to form the pattern including the second conductive structures includes:
removing, through chemical mechanical polishing, a part of the second conductive layer on a surface of the second buffer layer facing away from the dielectric substrate, and planarizing a surface facing away from the dielectric substrate of a part of the second conductive layer in the second hollowed-out pattern, to form the second conductive structure.

The first conductive layer has a thickness greater than the first buffer layer by 1 μm to 5 μm; and/or, the second conductive layer has a thickness greater than the second buffer layer by 1 μm to 5 μm.

The seed layer includes an auxiliary film layer and a conductive film layer arranged in a stack, wherein the auxiliary film layer is configured to increase adhesion between the conductive film layer and the dielectric substrate; and the auxiliary film layer in the first conductive structure contacts a sidewall of the first hollowed-out pattern, and the auxiliary film layer in the second conductive structure contacts a sidewall of the second hollowed-out pattern.

A surface of the first buffer layer facing away from the dielectric substrate is flush with a surface of the first conductive structure facing away from the dielectric substrate; and
a surface of the second buffer layer facing away from the dielectric substrate is flush with a surface of the second conductive structures facing away from the dielectric substrate.

The method further includes:
forming a first protective layer on a side of the first conductive structure facing away from the dielectric substrate.

The first connection electrode is filled into the first connection via.

The first buffer layer is made of an organic dielectric material; and/or, the second buffer layer is made of an organic dielectric material.

The first conductive structure and the second conductive structure are electrically connected through the first connection electrode to form a coil structure of an inductor.

An embodiment of the present disclosure provides an electronic device, including any integrated substrate as described above.

### BRIEF DESCRIPTION OF DRAWINGS

FIG. 1 is a flowchart of a method for manufacturing an integrated substrate in a first example.

FIG. 2 is a flowchart of a method for manufacturing an integrated substrate in a second example.

FIG. 3 is a flowchart of a method for manufacturing an integrated substrate in a third example.

FIG. 4 is a schematic structural diagram of a seed layer according to an embodiment of the present disclosure.

FIG. 5 is a schematic structural diagram of an integrated substrate according to an embodiment of the present disclosure.

### DETAIL DESCRIPTION OF EMBODIMENTS

To improve understanding of the technical solution of the present disclosure for those skilled in the art, the present disclosure will be described in detail with reference to accompanying drawings and specific implementations.

Unless otherwise defined, technical or scientific terms used in the present disclosure are intended to have general meanings as understood by those skilled in the art to which the present disclosure belongs. The words “first”, “second” and similar terms used in the present disclosure do not denote any order, quantity, or importance, but are used merely for distinguishing different components from each other. Likewise, the words “a”, “an”, or “the” and similar referents do not denote a limitation of quantity, but rather denote the presence of at least one. The word “comprise” or “include” or the like means that the element or item preceding the word contains elements or items that appear after the word or equivalents thereof, but does not exclude other elements or items. The terms “connected” or “coupled” and the like are not restricted to physical or mechanical connection, but may include electrical connection, either direct or indirect. The words “upper”, “lower”, “left”, “right”, or the like are merely used to indicate a relative positional relationship, and when an absolute position of the described object is changed, the relative positional relationship may be changed accordingly.

The integrated substrate in the embodiments of the present disclosure mainly refers to a glass substrate integrated with passive devices. In other words, the dielectric substrate of the integrated substrate in the embodiments of the present disclosure is a glass substrate, but it should be understood that it may also be a silicon substrate, an LTCC substrate, or the like. Passive devices on the integrated substrate include, but are not limited to, capacitors, inductors, resistors, and the like. As a main energy consumption part in an electronic product, the integrated substrate is desired to have greatly reduced electromagnetic loss of devices at a radio frequency front end, and due to the advantages of a glass substrate in the aspects of dielectric loss, cost and the like, the glass substrate integrated with passive devices has gradually become a main current circuit.

The passive devices integrated on the glass substrate are divided into 2D passive devices and 3D passive devices according to presence or absence of connection vias in the glass substrate. The 2D passive devices refer to devices, such as inductors, capacitors or the like, which are formed on a conductive layer on a surface of the glass substrate and a dielectric layer between conductive layers. The 3D passive devices refer to devices, such as inductors, capacitors or the like, which are formed by forming conductive layers on upper and lower surfaces of the glass substrate, respectively, and then electrically connecting the conductive layers on the upper and lower surfaces of the glass substrate through a connection via running through the glass substrate. In the embodiments of the present disclosure, the description is given only by taking the case where 3D passive devices are formed on an integrated substrate as an example.

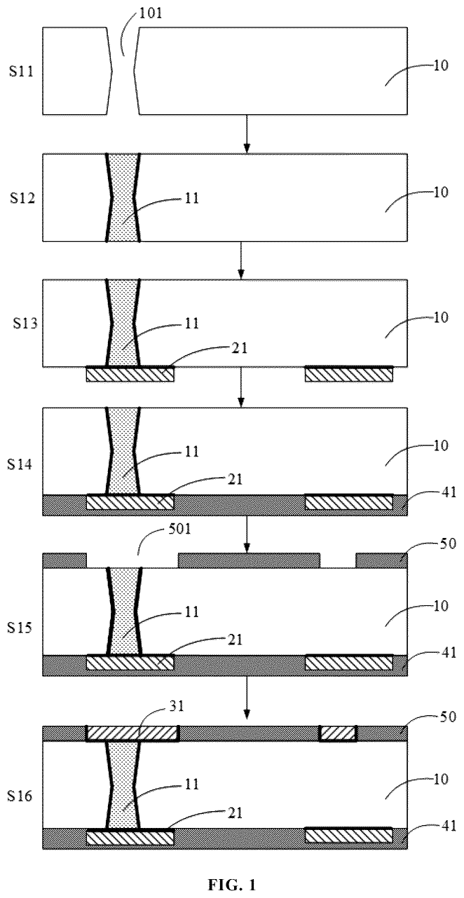

In a first example, FIG. 1 is a flowchart of a method for manufacturing an integrated substrate in a first example. As shown in FIG. 1, a method for manufacturing an integrated substrate is provided, which specifically includes the following steps S11 to S16:

At S11, providing a dielectric substrate 10. The dielectric substrate 10 includes a first surface and a second surface opposite to each other in a thickness direction of the dielectric substrate 10, and the dielectric substrate 10 has a first connection via 101 running through the dielectric substrate 10 in the thickness direction of the dielectric substrate 10.

In some examples, the dielectric substrate 10 includes, but is not limited to, a glass substrate, and the embodiments of the present disclosure are given by taking the glass substrate as an example. The glass substrate has a thickness between about 0.1 mm and about 1 mm.

The first connection via 101 in the dielectric substrate 10 may be formed by performing via-last on the dielectric substrate 10 in various methods. The methods include, for example, sand blasting, photosensitive glass, focused discharge, plasma etching, laser ablation, an electrochemical process, laser-induced etching, and the like. Different methods have different advantages and disadvantages and different application ranges. For example, sand blasting is a simple process which can be used to form a first connection via 101 having a relatively large aperture, and is only suitable for manufacturing a first connection via 101 with an aperture greater than 200 μm. Photosensitive glass is a simple process which can be used to form a first connection via 101 of high density and high aspect ratio. Focused discharge has the advantage of high via-forming speed. Plasma etching can be used to form a first connection via of low sidewall roughness. Laser ablation can be used to form a first connection via 101 of high density and high aspect ratio, but with a high roughness. The electrochemical process has the advantages of low cost, simple equipment and high via-forming speed, but the formed first connection via 101 has a relatively large diameter. Laser-induced etching has the advantages of high via-speed, capability of forming a first connection via of high density and high aspect ratio with no damage inside the via, but the laser equipment is expensive. Taking laser-induced etching as an example, a back side of the substrate is subjected to via-last through laser-induced etching here. Firstly, laser-induced modification is performed by laser on a position where a first connection via 101 is to be formed, and then wet etching is performed on the modified position with hydrofluoric acid or thermokalite to form the via. Since via-last can be implemented only in a single-side etching manner, the obtained via has an inverted cone shape. For the punching method by laser-induced etching, the single-side-etched inverted cone-shaped via is a typical characteristic of the via-last on the back of the first connection via 101.

The first connection via 101 formed in step S11 has an aperture between about 20 μm to about 120 μm.

At S12, forming a first connection electrode 11 in the first connection via 101.

In some examples, in step S12, a first auxiliary film layer is formed by means including, but not limited to, magnetron sputtering, and then a first conductive film layer is continuously sputtered to form a first seed layer. The first seed layer is electroplated, after which excessive electroplated copper on the first surface and the second surface is removed through chemical mechanical polishing (CMP) to form the first connection electrode 11 filled into the first connection via 101.

The first auxiliary film layer functions to enhance adhesion of the first conductive film layer. The first auxiliary film layer is made of a material including, but is not limited to, titanium (Ti), and The first conductive film layer is made of a material including, but is not limited to, copper (Cu). The first auxiliary film layer has a thickness between about 20 nm and about 200 nm, and the first conductive film layer has a thickness between about 100 nm and about 1000 nm.

At S13, forming a first conductive structure 21 on the first surface of the dielectric substrate 10.

In some examples, step S13 may include: sequentially forming a second auxiliary film layer and a second conductive film layer, which are used as a second seed layer, on the first surface of the dielectric substrate 10 through a process including, but not limited to, magnetron sputtering, then electroplating the second seed layer, where the electroplated second seed layer typically has a thickness greater than 2 μm to 10 μm, and then patterning the second seed layer to form the first conductive structure 21.

The second auxiliary film layer may be a molybdenum (Mo) and nickel (Ni) alloy layer with a thickness between about 20 nm and about 200 nm. The second conductive film layer may be a copper (Cu) layer with a thickness between about 100 nm and about 1000 nm. The second auxiliary film layer is provided to enhance adhesion of the second conductive film layer.

At S14, forming a first protective layer 41 on a side of the first conductive structure 21 facing away from the dielectric substrate 10.

In some examples, step S14 may specifically include depositing and forming the first protective layer 41 through a standard process such as PECVD, and then curing the first protective layer 41. The first protective layer 41 is used to prevent water and oxygen erosion of devices formed on the first surface of the dielectric substrate 10. The first protective layer 41 has a thickness of 2 μm to 8 μm. The first protective layer 41 may be made polyimide (PI) or the like.

At S15, flipping over the dielectric substrate 10, and forming a buffer layer 50 on the second surface of the dielectric substrate 10. A hollowed-out pattern of the buffer layer 50 is the same as a pattern of a second conductive structures 31 to be formed.

In some examples, the buffer layer 50 is an organic dielectric layer made of, for example, polyimide (PI), with a thickness of 2 μm to 10 μm. Step S15 may specifically include coating a layer of PI glue, and then performing exposure, development, and curing to form the buffer layer 50 with the hollowed-out pattern.

At S16, forming the second conductive structure 31 on the second surface.

In some examples, step S16 may include sequentially forming a third auxiliary film layer and a third conductive film layer, which are used as a third seed layer, through a process including, but not limited to, magnetron sputtering, then electroplating the third seed layer, where the electroplated third seed layer typically has a thickness between about 2 μm and about 12 μm. Next, with the buffer layer 50 as a stop layer, the electroplated second seed layer on a surface of the buffer layer 50 facing away from the dielectric substrate 10 is removed through chemical mechanical polishing (CMP), and a surface of the electroplated second seed layer facing away from the dielectric substrate 10 in the hollowed-out pattern is planarized to form the second conductive structure 31.

The third auxiliary film layer may be a molybdenum (Mo) and nickel (Ni) alloy layer with a thickness between about 20 nm and about 200 nm. The third conductive film layer may be a copper (Cu) layer with a thickness between about 100 nm and about 1000 nm. The third auxiliary film layer is provided to enhance adhesion of the second conductive film layer.

In some examples, the first conductive structure 21 and the second conductive structure 31 on the integrated substrate are electrically connected through the first connection electrode 11 to form a coil structure of an inductor. In some examples, a part of the first conductive structure 21 may be used as a first plate of a capacitor. The method for manufacturing an integrated substrate may further include forming an interlayer dielectric layer, a second plate of the capacitor, and other structures on a side of the second conductive structure 31 facing away from the dielectric substrate 10, which are not explained here one by one.

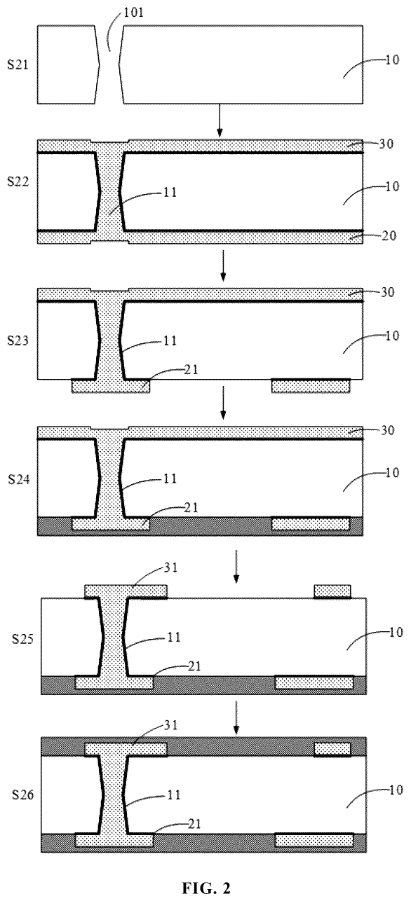

Second example: FIG. 2 is a flowchart of a method for manufacturing an integrated substrate in a second example. As shown in FIG. 2, this example also provides a method for manufacturing an integrated substrate, which specifically includes the following steps S21 to S26:

At S21, providing a dielectric substrate 10. The dielectric substrate 10 includes a first surface and a second surface opposite to each other in a thickness direction of the dielectric substrate 10, and the dielectric substrate 10 has a first connection via 101 running through the dielectric substrate 10 in the thickness direction of the dielectric substrate 10.

Step S21 may adopt the same process step as S11, which is not repeated here.

At S22, forming seed layers on both the first surface and the second surface of the dielectric substrate 10, electroplating the seed layers to form a first conductive layer 20 on the first surface side, a second conductive layer 30 on the second surface side, and a first connection electrode 11 in the first connection via 101.

In some examples, auxiliary film layers and conductive film layers, which are used as seed layers, are sequentially formed on the first surface and the second surface of the dielectric substrate 10 through a process including, but not limited to, magnetron sputtering, then the seed layers are electroplated to form a first conductive layer 20 on the first surface, and form a second conductive layer 30 on the first surface, and the first connection via 101 is filled with a conductive material to form a first connection electrode 11.

It should be noted that the first conductive layer 20 on the first surface has a thickness equivalent to a first conductive structure 21 to be formed, and the second conductive layer 30 on the second surface has a thickness greater than a second conductive structure 31 to be formed by 1 μm to 5 μm.

The auxiliary film layer may be a molybdenum (Mo) and nickel (Ni) alloy layer with a thickness between about 20 nm and about 200 nm. The conductive film layer may be a copper (Cu) layer with a thickness between about 100 nm and about 1000 nm. The auxiliary film layer is provided to enhance adhesion of the conductive film layer.

At S23, patterning the first conductive layer 20 to form a pattern including the first conductive structure 21.

In some examples, step S23 may include forming a first photoresist layer on a side of the first conductive layer 20 facing away from the dielectric substrate 10, performing exposure and development to form a mask pattern of the first conductive structure 21, removing an exposed portion of the first conductive layer 20, and then removing the remaining first photoresist layer to form a first conductive pattern.

At S24, forming a first protective layer 41 on a side of the first conductive structure 21 facing away from the dielectric substrate 10.

In some examples, step S24 may specifically include depositing and forming the first protective layer 41 through a standard process such as PECVD, and then curing the first protective layer 41. The first protective layer 41 is used to prevent water and oxygen erosion of devices formed on the first surface of the dielectric substrate 10. The first protective layer 41 has a thickness of 2 μm to 8 μm. The first protective layer 41 may be made polyimide (PI) or the like.

At S25, processing the second conductive layer 30 to form a pattern including the second conductive structures 31.

In some examples, step S25 may include grinding the second conductive layer 30 to a desired thickness through chemical mechanical polishing (CMP), then forming a second photoresist layer on a side of the second conductive layer 30 facing away from the dielectric substrate 10, performing exposure and development to form a mask pattern of the second conductive structures 31, removing an exposed portion of the second conductive layer 30, and then removing the remaining second photoresist layer to form a second conductive pattern.

At S26, forming a second protective layer 42 on a side of the second conductive structures 31 facing away from the dielectric substrate 10.

In some examples, the second protective layer 42 in step S26 may be manufactured through the same process and with the same material as the first protective layer 41 described above, and details are thus not repeated here.

In some examples, the first conductive structure 21 and the second conductive structure 31 on the integrated substrate are electrically connected through the first connection electrode 11to form a coil structure of an inductor. In some examples, a part of the first conductive structure 21 may be used as a first plate of a capacitor. The method for manufacturing an integrated substrate may further include forming an interlayer dielectric layer, a second plate of the capacitor, and other structures on a side of the second conductive structure 31 facing away from the dielectric substrate 10, which are not explained here one by one.

Comparing the first example with the second example, the first example involves a significantly more complex process flow than the second example.

In the first example, a: The first connection electrode 11 and the first conductive structure 21/second conductive structure 31 are separately manufactured. After the first connection electrode 11 is formed in the first connection via 101, the first connection electrode 11 is thermally expanded in the subsequent two curing processes, and then contracted with subsequent decrease of the temperature to press against the first connection via 101. Since there is no glass at both ends of the first connection via 101, thermal stress caused by expansion and contraction of the first connection electrode 11 is concentrated at both ends of the first connection via 101, increasing the risks of cracks. b: The first connection electrode 11 and the first conductive structure 21/second conductive structure 31 are separately manufactured. Both ends of the first connection electrode 11 are exposed before the first conductive structure 21 and the second conductive structure 31 are formed, and thus are susceptible to oxidation and contamination of foreign matters, and the like, leading to subsequent high contact resistance between the first connection electrode 11 and the first conductive structure 21 and the second conductive structure 31, and high risks of layer separation.

In the second example, although the first connection electrode 11, the first conductive structure 21, and the second conductive structure 31 are formed by one plating process, during patterning the first conductive structure 21 and the second conductive structure 31, alignment marks on the first photoresist layer and the second photoresist layer are hard to be recognized since both the first surface and the second surface of the dielectric substrate 10 are light-shielding material metals, making it difficult to complete photolithography.

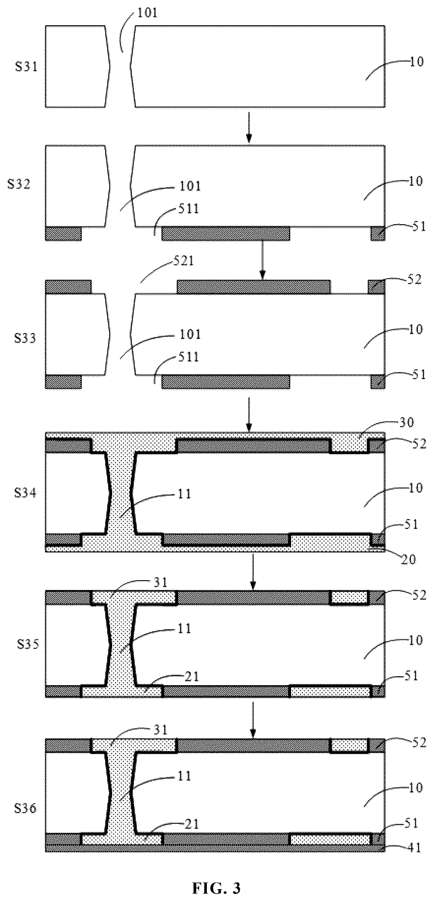

FIG. 3 is a flowchart of a method for manufacturing an integrated substrate in a third example. As shown in FIG. 3, in view of some problems in the first example and the second example, an embodiment of the present disclosure further provides a method for manufacturing an integrated substrate as described in the following third example, which specifically includes the following steps S31 to S36:

At S31, providing a dielectric substrate 10. The dielectric substrate 10 includes a first surface and a second surface opposite to each other in a thickness direction of the dielectric substrate 10, and the dielectric substrate 10 has a first connection via 101 running through the dielectric substrate 10 in the thickness direction of the dielectric substrate 10.

Step S31 may adopt the same process step as S11, which is not repeated here.

At S32, forming a first buffer layer 51 on the first surface of the dielectric substrate 10 through a patterning process. A first hollowed-out pattern 511 of the first buffer layer 51 is the same as a pattern of a first conductive structure 21 to be formed.

In some examples, the first buffer layer 51 is an organic dielectric layer made of, for example, polyimide (PI), with a thickness of 2 μm to 10 μm. Step S32 may specifically include depositing a layer of PI glue through a standard process such as PECVD, and then performing exposure, development, and curing to form the first buffer layer 51 with the first hollowed-out pattern 511.

At S33, forming a second buffer layer 52 on the second surface of the dielectric substrate 10 through a patterning process. A second hollowed-out pattern 521 of the second buffer layer 52 is the same as a pattern of a second conductive structures 31 to be formed.

In some examples, the second buffer layer 52 is an organic dielectric layer made of, for example, polyimide (PI), with a thickness of 2 μm to 10 μm. Step S33 may specifically include depositing a layer of PI glue through a standard process such as PECVD, and then performing exposure, development, and curing to form the second buffer layer 52 with the second hollowed-out pattern 521.

It should be noted that the sequence of step S32 and step S33 may be reversed.

At S34, forming seed layers on a side of the first buffer layer 51 facing away from the first surface, and on a side of the second buffer layer 52 facing away from the second surface, and then the seed layer is electroplated to form a first conductive layer 20 on the first surface side, a second conductive layer 30 on the second surface side, and a first connection electrode 11 in the first connection via 101.

In some examples, operation S34 may include sequentially forming auxiliary film layers and conductive film layers, which are used as seed layers, on a side of the first buffer layer 51 facing away from the first surface and on a side of the second buffer layer 52 facing away from the second surface through a process including, but not limited to, magnetron sputtering, then electroplating the seed layers to form a first conductive layer 20 on the first surface, and form a second conductive layer 30 on the first surface, and filling the first connection via 101 with a conductive material to form a first connection electrode 11. The first conductive layer 20 has a thickness greater than the first buffer layer 51 by 1 μm to 5 μm; and similarly, the thickness of the second conductive layer 30 is 1 μm to 5 μm thicker than the second buffer layer 52.

The auxiliary film layer may be a molybdenum (Mo) and nickel (Ni) alloy layer with a thickness between about 20 nm and about 200 nm. The conductive film layer may be a copper (Cu) layer with a thickness between about 100 nm and about 1000 nm. The auxiliary film layer is provided to enhance adhesion of the conductive film layer.

At S35, processing the first conductive layer 20 and the second conductive layer 30 respectively, to form a pattern including the first conductive structure 21.

In some examples, the step S35 specifically includes removing, through chemical mechanical polishing (CMP), a part of the first conductive layer 20 on a surface of the first buffer layer 51 facing away from the dielectric substrate 10, and planarizing a surface facing away from the dielectric substrate 10 of a part of the first conductive layer 20 in the first hollowed-out pattern 511, to form the first conductive structures 21; and similarly, removing, through chemical mechanical polishing (CMP), a part of the second conductive layer 30 on a surface of the second buffer layer 52 facing away from the dielectric substrate 10, and planarizing a surface facing away from the dielectric substrate 10 of a part of the second conductive layer 30 in the second hollowed-out pattern 521, to form the second conductive structure 31.

In some examples, a surface of the first conductive structures 21 formed in step S35 facing away from the dielectric substrate 10 is flush with a surface of the first buffer layer 51 facing away from the dielectric substrate 10, and a surface of the second conductive structure 31 facing away from the dielectric substrate 10 is flush with a surface of the second buffer layer 52 facing away from the dielectric substrate 10.

In some examples, the auxiliary film layer in the first conductive structure 21 contacts a sidewall of the first hollowed-out pattern 511, and the auxiliary film layer in the second conductive structure 31 contacts a sidewall of the second hollowed-out pattern 521. In this manner, the first conductive structure 21 and the second conductive structure 31 are more firmly bonded to the dielectric substrate 10.

At S36, forming a first protective layer 41 on a side of the first conductive structure 21 facing away from the dielectric substrate 10.

In some examples, step S14 may specifically include depositing and forming the first protective layer 41 through a standard process such as PECVD, and then curing the first protective layer 41. The first protective layer 41 is used to prevent water and oxygen erosion of devices formed on the first surface of the dielectric substrate 10. The first protective layer 41 has a thickness of 2 μm to 8 μm. The first protective layer 41 may be made polyimide (PI) or the like.

In some examples, the first conductive structure 21 and the second conductive structure 31 on the integrated substrate are electrically connected through the first connection electrode 11 to form a coil structure of an inductor. In some examples, a part of the first conductive structure 21 may be used as a first plate of a capacitor. The method for manufacturing an integrated substrate may further include forming an interlayer dielectric layer, a second plate of the capacitor, and other structures on a side of the second conductive structure 31 facing away from the dielectric substrate 10, which are not explained here one by one.

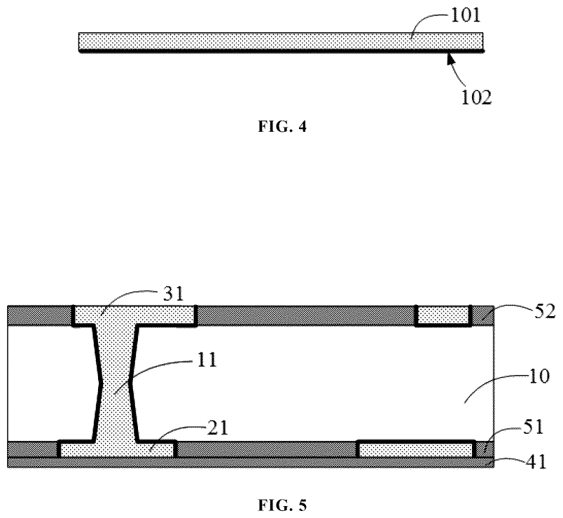

It should be noted that, as shown in FIG. 4, FIG. 4 is a schematic structural diagram of a seed layer according to an embodiment of the present disclosure. The first seed layer, the second seed layer, and the third seed layer mentioned in the first example and the second example may have the same structure as the seed layer in the third example, i.e., a seed layer composed of the auxiliary film layer 102 and the conductive film layer 101. In the electroplating process, the thickness of the auxiliary film layer 102 generally remains unchanged, while the thickness of the conductive film layer 101 will be increased.

Compared with the second example, for the integrated substrate formed in the method for manufacturing an integrated substrate of the third example, the auxiliary film layer in the first conductive structure 21 contacts a sidewall of the first hollowed-out pattern 511, and the auxiliary film layer in the second conductive structures 31 contacts a sidewall of the second hollowed-out pattern 521. In this manner, the first conductive structure 21 and the second conductive structure 31 are more firmly bonded to the dielectric substrate 10. In the manufacturing method of the third example, the first conductive structure 21 and the second conductive structure 31 formed subsequently are defined by the first buffer layer 51 and the second buffer layer 52 without alignment of a photoresist layer, thereby making the method easier to be implemented.

Compared with the first example, for the integrated substrate formed in the method for manufacturing an integrated substrate of the third example, the auxiliary film layer in the first conductive structure 21 contacts a sidewall of the first hollowed-out pattern 511, and the auxiliary film layer in the second conductive structure 31 contacts a sidewall of the second hollowed-out pattern 521. In this manner, the first conductive structure 21 and the second conductive structure 31 are more firmly bonded to the dielectric substrate 10. The manufacturing method of the third example has a relatively simple process flow.

FIG. 5 is a schematic structural diagram of an integrated substrate according to an embodiment of the present disclosure. As shown in FIG. 5, an embodiment of the present disclosure further provides an integrated substrate which may be manufactured in any of the above methods. Preferably, the integrated substrate is manufactured in the manufacturing method of the third example. Specifically, the integrated substrate includes: a dielectric substrate 10, a first buffer layer 51, a second buffer layer 52, a first conductive structure 21, a second conductive structure 31, and a first connection electrode 11.

The dielectric substrate 10 has a first surface and a second surface opposite to each other in a thickness direction of the dielectric substrate. The dielectric substrate 10 includes a first connection via 101 running through the dielectric substrate 10 in the thickness direction of the dielectric substrate 10. The first buffer layer 51 is disposed on the first surface side, and has a first hollowed-out pattern 511. The second buffer layer 52 is disposed on the second surface side, and has a second hollowed-out pattern 521. The first conductive structure 21 is located in the first hollowed-out pattern 511. The second conductive structures 31 is located in the second hollowed-out pattern 521. The first connection electrode 11 is located in the first connection via 101, and the first conductive structure 21 and the second conductive structure 31 are connected through, and form an integral structure with, the first connection electrode 11.

In some examples, a first protective layer 41 is provided on a side of the first conductive structure 21 facing away from the dielectric substrate 10. The first protective layer 41 is used to prevent water and oxygen erosion of devices formed on the first surface of the dielectric substrate 10. The first protective layer 41 has a thickness of 2 μm to 8 μm. The first protective layer 41 may be made polyimide (PI) or the like.

In some examples, the first conductive structure 21 and the second conductive structure 31 on the integrated substrate are electrically connected through the first connection electrode 11 to form a coil structure of an inductor. In some examples, a part of the first conductive structure 21 may be used as a first plate of a capacitor. The integrated substrate may further include an interlayer dielectric layer, a second plate of the capacitor, and other structures formed on a side of the second conductive structure 31 facing away from the dielectric substrate 10, which are not explained here one by one.

An embodiment of the present disclosure further provides an electronic device, which may include the integrated substrate as described above.

It will be appreciated that the above implementations are merely exemplary implementations for the purpose of illustrating the principle of the present disclosure, and the present disclosure is not limited thereto. Various modifications and improvements can be made by those skilled in the art without departing from the spirit and essence of the present disclosure. Accordingly, all of the modifications and improvements also fall into the protection scope of the present disclosure.

1. An integrated substrate, comprising:
a dielectric substrate having a first surface and a second surface opposite to each other in a thickness direction of the dielectric substrate, wherein the dielectric substrate comprises a first connection via running through the dielectric substrate in the thickness direction of the dielectric substrate;
a first buffer layer on the first surface side and provided with a first hollowed-out pattern;
a second buffer layer on the second surface side and provided with a second hollowed-out pattern;
a first conductive structure in the first hollowed-out pattern;
a second conductive structure in the second hollowed-out pattern; and
a first connection electrode in the first connection via, wherein the first conductive structure and the second conductive structure are connected through, and form an integral structure with, the first connection electrode.

2. The integrated substrate according to claim 1, further comprising a first protective layer on a side of the first conductive structure facing away from the dielectric substrate.

3. The integrated substrate according to claim 1, wherein the first connection electrode is filled into the first connection via.

4. The integrated substrate according to claim 1, wherein the first conductive structure and the second conductive structure are electrically connected through the first connection electrode to form a coil structure of an inductor.

5. A method for manufacturing an integrated substrate, comprising:
providing a dielectric substrate having a first surface and a second surface opposite to each other in a thickness direction of the dielectric substrate, wherein the dielectric substrate comprises a first connection via running through the dielectric substrate in the thickness direction of the dielectric substrate;
forming a pattern comprising a first buffer layer on the first surface through a patterning process, wherein a first hollowed-out pattern of the first buffer layer is the same as a pattern of a first conductive structure to be formed;
forming a pattern comprising a second buffer layer on the second surface through a patterning process, wherein a second hollowed-out pattern of the second buffer layer is the same as a pattern of a second conductive structures to be formed;
forming seed layers on a side of the first buffer layer facing away from the first surface, and on a side of the second buffer layer facing away from the second surface, and electroplating the seed layers to form a first conductive layer on the first surface side, a second conductive layer on the second surface side, and a first connection electrode in the first connection via;
patterning the first conductive layer to form a pattern comprising the first conductive structure; and
patterning the second conductive layer to form a pattern comprising the second conductive structures, wherein the second conductive structure is connected to the first conductive structure through the first connection electrode to form an integral structure.

6. The method for manufacturing an integrated substrate according to claim 5, wherein the step of patterning the first conductive layer to form the pattern comprising the first conductive structure comprises:
removing, through chemical mechanical polishing, a part of the first conductive layer on a surface of the first buffer layer facing away from the dielectric substrate, and planarizing a surface facing away from the dielectric substrate of a part of the first conductive layer in the first hollowed-out pattern, to form the first conductive structure.

7. The method for manufacturing an integrated substrate according to claim 5, wherein the step of patterning the second conductive layer to form the pattern comprising the second conductive structures comprises:
removing, through chemical mechanical polishing, a part of the second conductive layer on a surface of the second buffer layer facing away from the dielectric substrate, and planarizing a surface facing away from the dielectric substrate of a part of the second conductive layer in the second hollowed-out pattern, to form the second conductive structure.

8. The method for manufacturing an integrated substrate according to claim 5, wherein the first conductive layer has a thickness greater than the first buffer layer by 1 μm to 5 μm; and/or, the second conductive layer has a thickness greater than the second buffer layer by 1 μm to 5 μm.

9. The method for manufacturing an integrated substrate according to claim 5, wherein the seed layer comprises an auxiliary film layer and a conductive film layer arranged in a stack, wherein the auxiliary film layer is configured to increase adhesion between the conductive film layer and the dielectric substrate; and the auxiliary film layer in the first conductive structure contacts a sidewall of the first hollowed-out pattern, and the auxiliary film layer in the second conductive structure contacts a sidewall of the second hollowed-out pattern.

10. The method for manufacturing an integrated substrate according to claim 5, wherein a surface of the first buffer layer facing away from the dielectric substrate is flush with a surface of the first conductive structure facing away from the dielectric substrate; and
a surface of the second buffer layer facing away from the dielectric substrate is flush with a surface of the second conductive structures facing away from the dielectric substrate.

11. The method for manufacturing an integrated substrate according to claim 5, further comprising:
forming a first protective layer on a side of the first conductive structure facing away from the dielectric substrate.

12. The method for manufacturing an integrated substrate according to claim 5, wherein the first connection electrode is filled into the first connection via.

13. The method for manufacturing an integrated substrate according to claim 5, wherein the first buffer layer is made of an organic dielectric material.

14. The method for manufacturing an integrated substrate according to claim 5, wherein the first conductive structure and the second conductive structure are electrically connected through the first connection electrode to form a coil structure of an inductor.

15. An electronic device, comprising the integrated substrate according to claim 1.

16. The method for manufacturing an integrated substrate according to claim 13, wherein the second buffer layer is made of an organic dielectric material.

17. The method for manufacturing an integrated substrate according to claim 5, wherein the second buffer layer is made of an organic dielectric material.

18. An electronic device, comprising the integrated substrate according to claim 2.

19. An electronic device, comprising the integrated substrate according to claim 3.

20. An electronic device, comprising the integrated substrate according to claim 4.
